(19) United States
(12) Patent Application Publication
(10) Pub. No.: US 2006/0279306 A1
(43) Pub. Date: Dec. 14, 2006

(54) Test equipment of semiconductor devices

(75) Inventors: Sueharu Miyakawa, Oita (JP); Ryoji Ikebe, Oita (JP)

Correspondence Address: MCDERMOTT WILL & EMERY LLP, 600 13TH STREET, N.W., WASHINGTON, DC, 20005-3096, US

(73) Assignee: STK TECHNOLOGY, LTD.

(21) Appl. No.: 11/447,871

(22) Filed: Jun. 7, 2006

(30) Foreign Application Priority Data
Jun. 9, 2005 (JP) JP2005-169039

(51) Int. Cl. G01R 31/02

(52) U.S. Cl. 324/763

(57) ABSTRACT

An test equipment includes a tester board that can be housed in a chamber, a plurality of sockets that are attached on a first main surface of the tester board and mounted respectively with semiconductor devices to be tested, a plurality of device testing units that are attached on a second main surface of the tester board and input predetermined test signals to the semiconductor devices as well as evaluate the semiconductor devices respectively based on the output signals output from the semiconductor devices according to the test signals, and a heat sink plate that cools off the device testing units, where a burn-in test and a characteristic test are carried out for the semiconductor devices while the semiconductor devices mounted on the sockets are heated, and the device testing units are cooled off by a dissipating unit in the chamber.

### BACKGROUND OF THE INVENTION

1. Field of the Invention

The present invention relates to a test equipment of semiconductor devices, and more particularly to a test equipment that carries out a burn-in test to secure product reliability and a characteristic test to weed out defective items.

2. Description of the Related Art

A production process to complete a semiconductor device such as semiconductor memory integrated circuit (IC) and system large scale integrated circuit (LSI) is very complex and delicate, and factors that cause failures to occur exist everywhere. That is, problems in designing, problems in inspection, problems in use including environment after a product is delivered to a user and circuit structure, and the like are included in the factors. Further, in the production process, factors leading to failures exist in silicone substrate, diffusion passivation, wiring electrode, frame, packaging, die bonding, wire bonding, sealing, and the like, respectively.

The main failure mode includes surface defect (e.g. ion contamination), oxide film defect (pin hole), metal wiring defect, input-output circuit defect, and the like.

Tests to discriminate semiconductor devices involving these failure modes include a burn-in test to secure product reliability and a characteristic test (selection test) to weed out defective items.

In the burn-in test with the use of a burn-in device, screening is carried out to weed out an early failure by operating a semiconductor device for a certain time while applying a rated voltage or a voltage ten to twenty percent higher than that under heating, for example, at about 125 degrees C.

In the characteristic test with the use of a memory tester, a semiconductor device is tested for whether it has characteristics described on the data sheet of the product by combining factors that represent various test patterns such as temperature from high temperature (ca. 85 degrees C.) to low temperature (equal to or lower than 0 degree C.), operation speed from highest operation speed to low operation speed, and power voltage at highest voltage and at lowest voltage.

Accompanied by the speed-up of semiconductor device, prices of test equipments for semiconductor device such as burn-in device and memory tester have become high, and the rate of test cost in retail price of a semiconductor device has become larger.

Accordingly, a burn-in tester in which functions of a burn-in device and part of those of a memory tester are integrated is known for decreasing the test cost of a semiconductor device. This burn-in tester is designed to carry out test items requiring relatively slow test speed and a long time (for example, long cycle test, interference test between memory cells) in parallel with a burn-in test with the use of a burn-in device in order to reduce the load of the memory tester.

It should be noted that there are documents describing technologies related to test equipment for semiconductor devices, such as Japanese Patent Application Laid-Open Publication No. 2001-349925, Japanese Patent Application Laid-Open Publication No. 2003-315405, and Japanese Patent Application Laid-Open Publication No. 2004-045325.

[Patent document 1] Japanese Patent Application Laid-Open Publication No. 2001-349925

[Patent document 2] Japanese Patent Application Laid-Open Publication No. 2003-315405

[Patent document 3] Japanese Patent Application Laid-Open Publication No. 2004-045325

In the conventional burn-in tester described above, semiconductor devices (DUT: device under test) to be tested are packaged on a tester board and housed in the inside of a chamber, which is connected to an electronic circuit (device testing unit) such as a pattern generator (PG), a driver (DR), and a power supply provided in the outside of the chamber.

Owing to this, a large number of control signals were needed in order to test a large number of semiconductor devices simultaneously, and a wiring capacity of a printed circuit board became large due to parallel wiring in order to reduce pieces of the signal. The test speed was approximately 10 MHz in general, and about 20 MHz was the limitation even if speed-up was tried.

Although the test process is made a little more efficient, it is hardly to say that the conventional burn-in testers contribute sufficiently to a reduction in test cost.

On the other hand, a technology to inspect a number of LSIs formed on a wafer all together by shifting burn-in from at the package level to at the wafer level has been proposed; however, it is difficult to contact a large number of electrodes formed on the LSIs on the wafer with probes all together.

In order to solve such problems, it is conceivable that a built-in self-test (BIST) having a self-diagnosis function in the inside of each semiconductor device is designed, thereby reducing the number of contacts with the electrodes by reducing the number of the probes. However, a device suitable for BIST for each semiconductor device is needed.

### SUMMARY OF THE INVENTION

Accordingly, an object of the present invention is to provide a test equipment of semiconductor devices that can realize a reduction in test cost.

To solve the above problems, the test equipment of semiconductor devices of the present invention includes a chamber, a tester board that can be housed in the inside of the chamber, a plurality of sockets that are attached on a first main surface of the tester board and mounted with semiconductor devices to be tested, a plurality of device testing units that are attached on a second main surface on the side opposite to the first main surface of the tester board and input predetermined test signals to one or a plurality of the semiconductor devices as well as evaluate the semiconductor devices based on the output signals output from the semiconductor devices according to the test signals, and a cooling unit that cools off the device testing units, where a burn-in test and a characteristic test for the semiconductor devices are carried out while the semiconductor devices mounted on the sockets respectively are heated and the device testing units are cooled off by the cooling unit in the chamber.

Owing to this, the burn-in test and the characteristic test can be carried out at the same time, and therefore, the test process for semiconductor device is made efficient, thereby making it possible to improve the test processing ability significantly and realize a reduction in test cost of semiconductor device.

Further, to solve the above problems, the test equipment of semiconductor devices of the present invention includes the chamber, the tester board that can be housed in the inside of the chamber, a plurality of the sockets that are attached on the first main surface of the tester board and mounted with the semiconductor devices to be tested, the device testing units that are provided on the second main surface on the side opposite to the first main surface of the tester board with sandwiching the tester board in one to one relation to the semiconductor devices mounted on the sockets, respectively, and input predetermined test signals to the semiconductor devices as well as evaluate the semiconductor devices based on the output signals output from the semiconductor devices according to the test signals, and the cooling unit that cools off the device testing units, where the device testing unit is provided with a waveform generating unit that generates a waveform to be input to the semiconductor device, the burn-in test and the characteristic test for the semiconductor device are carried out while the semiconductor devices mounted on the sockets respectively are heated and the device testing units are cooled off by the cooling unit in the chamber.

Owing to this, the burn-in test and the characteristic test can be carried out at the same time, and therefore, the test process for semiconductor device is made efficient, thereby making it possible to improve the test processing ability significantly and realize a reduction in test cost of semiconductor device.

Furthermore, the distance between the device testing unit and the semiconductor device can be made short, and therefore, the transient response speed becomes faster, thereby allowing high-speed tests. Still further, since space for wiring arrangement on the tester board can be reduced, realization of packaging of the semiconductor devices in a high density becomes possible.

Still further, since the semiconductor devices that are test targets are isolated from each other and the influence of operation noise of the adjacent semiconductor device is significantly reduced, realization of making the test time short becomes possible when a number of semiconductor devices are tested simultaneously.

In one exemplary embodiment of the present invention, the cooling unit is a heat sink plate that is attached to the tester board so as to come in contact with the device testing units and formed with flow paths where a liquid refrigerant flows in the inside of the heat sink plate.

Owing to this, the cooling unit can be realized with saving in space, and therefore, the space efficiency inside the chamber is not hampered.

Further, to solve the above problems, the test equipment of semiconductor devices of the present invention includes the chamber, the tester board that can be housed inside the chamber, a plurality of the sockets that are attached on the first main surface of the tester board and mounted with the semiconductor devices to be tested, a plurality of the device testing units that are attached on the second main surface on the side opposite to the first main surface of the tester board and input predetermined test signals to one or a plurality of the semiconductor devices as well as evaluate the semiconductor devices based on the output signals output from the semiconductor devices according to the test signals, and a heating unit that heats the semiconductor devices, where the burn-in test and the characteristic test are carried out while the semiconductor devices mounted on the sockets, respectively, are heated by the heating unit.

Owing to this, the burn-in test and the characteristic test can be carried out at the same time, and therefore, the test process for semiconductor device is made efficient, thereby making it possible to improve the test processing ability significantly and realize a reduction in test cost of semiconductor device.

Still further, to solve the above problems, the test equipment of semiconductor devices of the present invention includes the chamber, the tester board that can be housed in the inside of the chamber, a plurality of the sockets that are attached on the first main surface of the tester board and mounted with the semiconductor devices to be tested, the device testing units that are provided on the second main surface on the side opposite to the first main surface of the tester board with sandwiching the tester board in one to one relation to the semiconductor devices mounted on the sockets, respectively, and input predetermined test signals to the semiconductor devices as well as evaluate the semiconductor devices based on the output signals output from the semiconductor devices according to the test signals, and the heating unit that heats the semiconductor devices, where the device testing unit is provided with the waveform generating unit that generates a waveform input to the semiconductor device, and the burn-in test and the characteristic test are carried out while the semiconductor devices mounted on the sockets respectively are heated by the heating unit.

Owing to this, the burn-in test and the characteristic test can be carried out at the same time, and therefore, the test process for semiconductor device is made efficient, thereby making it possible to improve the test processing ability significantly and realize a reduction in test cost of semiconductor device.

Still further, the distance between the device testing unit and the semiconductor device can be made short, and therefore, the transient response speed becomes faster, thereby allowing high-speed tests. Still further, since space for wiring arrangement on the tester board can be reduced, realization of packaging of the semiconductor devices in a high density becomes possible.

Still further, since the semiconductor devices that are test targets are isolated from each other and the influence of operation noise of the adjacent semiconductor device is significantly reduced, realization of making the test time short becomes possible when a number of semiconductor devices are tested simultaneously.

In an exemplary embodiment of the present invention, it is featured that the waveform generating unit is at least any one of the pattern generator and the waveform generator.

In a further exemplary embodiment of the present invention, the device testing unit further includes the driver that inputs a generated waveform to the semiconductor device.

In a still further exemplary embodiment of the present invention, the device testing units are constructed of a single semiconductor integrated circuit device.

Owing to this, the number of parts of the device testing unit can be minimized, and therefore, low cost can be realized. Further, the number of parts packaged on the tester board becomes smaller, and cost of the packaging becomes minimum. Furthermore, power consumption can be reduced.

In a still further exemplary embodiment of the present invention, the sockets are structured so as to be provided detachably with respect to the tester board via connectors.

Owing to this, since mounting freely various kinds of sockets corresponding to the shapes of semiconductor devices that are test targets becomes possible, extremely high versatility can be obtained for the tester board.

### BRIEF DESCRIPTION OF THE DRAWINGS

FIG. 1 is a conceptual diagram to represent a test equipment of semiconductor devices that is one embodiment of the present invention;

FIG. 2 is a detailed diagram to explain a tester board housed in a chamber in the test equipment of semiconductor devices of FIG. 1;

FIG. 3 is a cross sectional view of the tester board of FIG. 2;

FIG. 4 is a perspective view to represent a cooling unit attached to the tester board; and

FIG. 5 is a block diagram to represent a functional structure of a device testing unit mounted on the tester board.

### DETAILED DESCRIPTION

Hereinafter, exemplary embodiments to carry out the present invention will be explained more specifically referring to the accompanying drawings. Here in the accompanying drawings, like members are designated by like reference numbers. Further, the same explanations are omitted in order to avoid repetition. Note that the present invention is not limited to the embodiments because the explanations here are given to the best mode for carrying out the present invention.

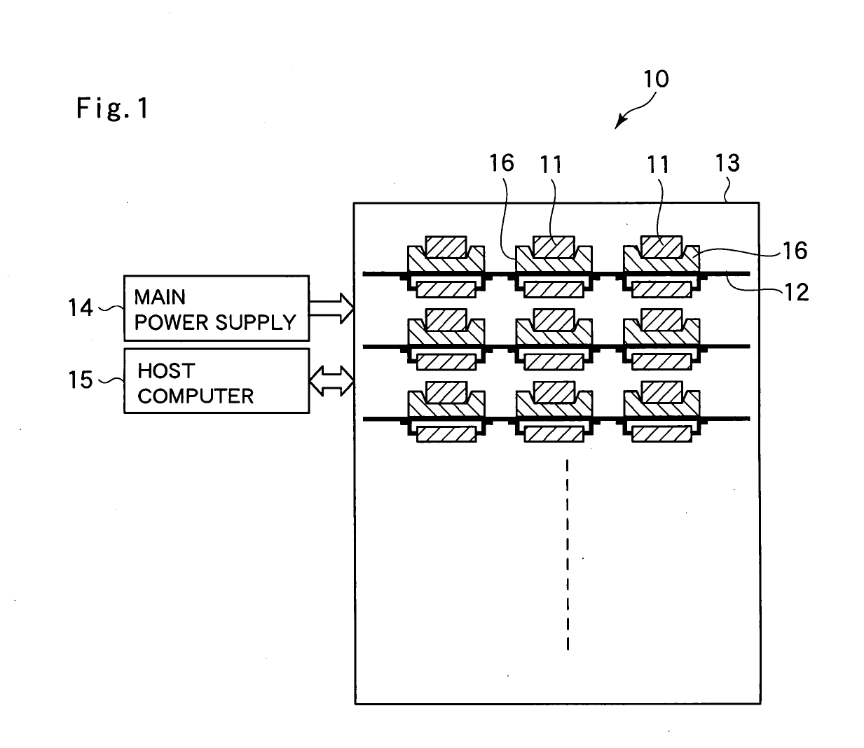

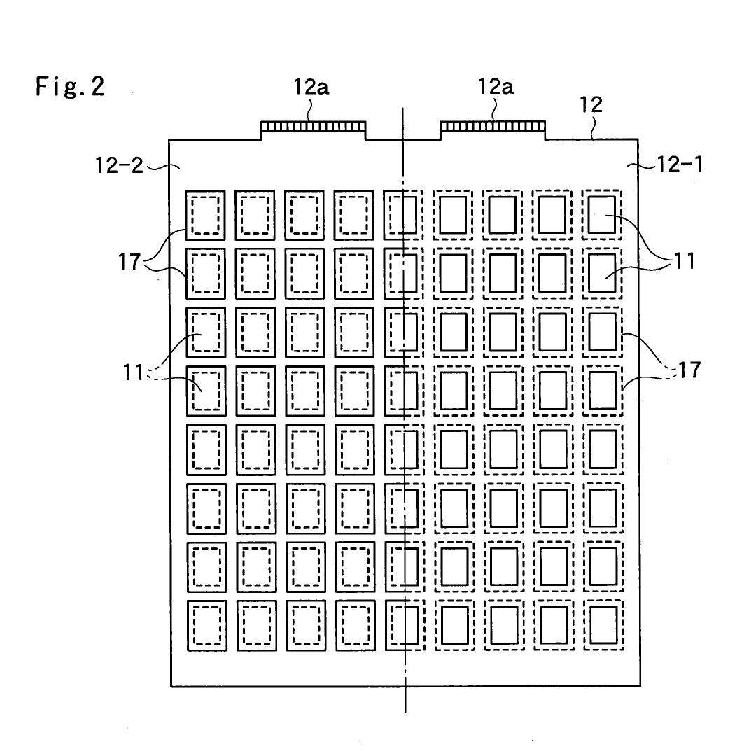

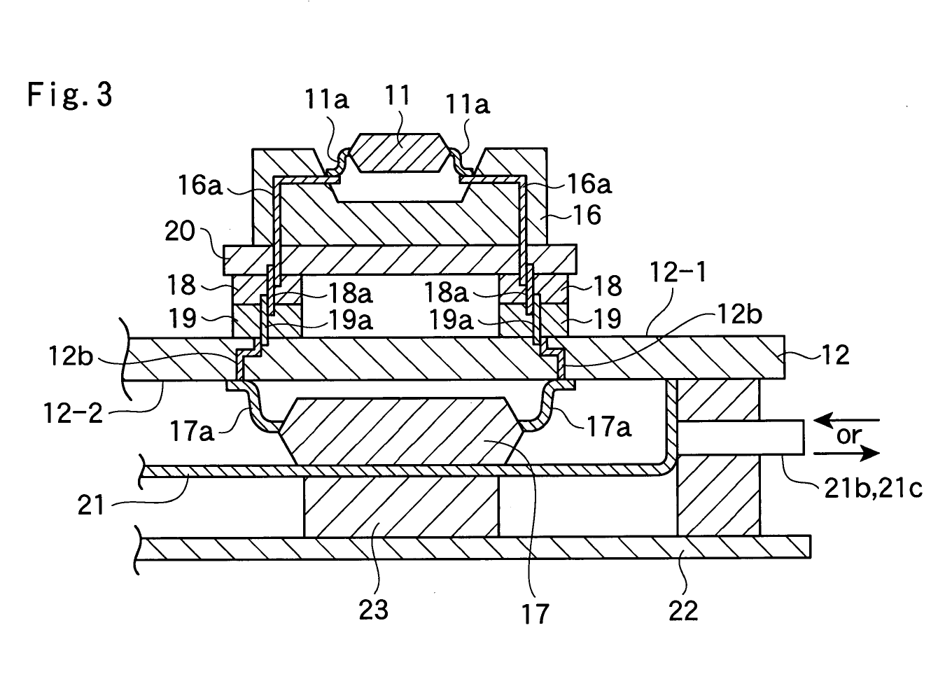

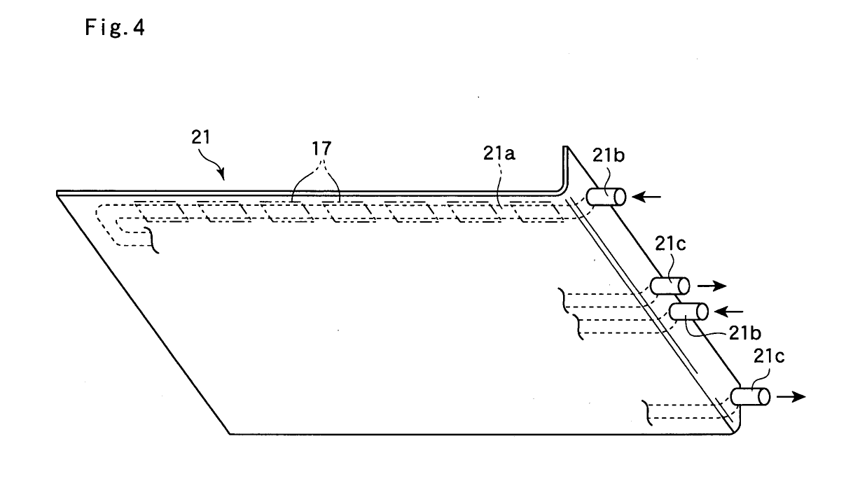

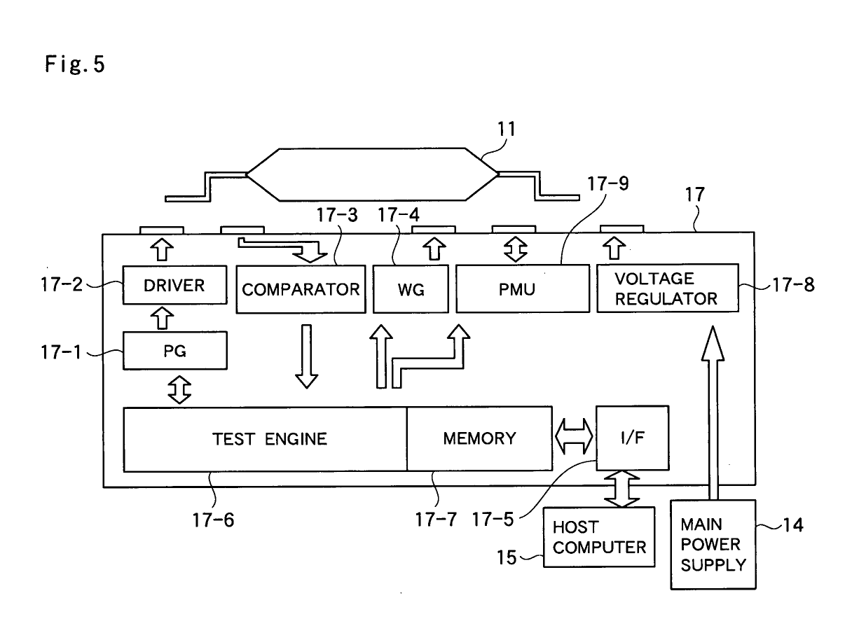

FIG. 1 is a conceptual diagram to represent a test equipment of semiconductor devices that is one embodiment of the present invention. FIG. 2 is a detailed diagram to explain a tester board housed in a chamber in the test equipment of semiconductor devices of FIG. 1. FIG. 3 is a cross sectional view of the tester board of FIG. 2. FIG. 4 is a perspective view to represent a cooling unit attached to the tester board. FIG. 5 is a block diagram to represent a functional structure of a device testing unit mounted on the tester board.

As shown in FIG. 1, a test equipment of semiconductor devices 10 in the present embodiment is provided with a chamber 13 in which tester boards 12 mounted with semiconductor devices (DUT) 11 that are test targets are housed, a main power supply 14 to supply power to the semiconductor devices 11 in the inside of the chamber 13, and a host computer 15 as a control unit to carry out various controls in inspection of the semiconductor devices 11.

Here, the host computer 15 has a central processing unit, an input-output unit, and a memory unit. The central processing unit carries out management of software such as inspection program, editing and translation of test program, implementation control of inspection, management of peripheral devices, data processing of test results, and the like. Further, a keyboard, a printer, a display, and the like are provided to the input-output device, which carries out input of control command, input and output of the inspection program, output of test results, and the like. The memory unit includes magnetic disk unit, optical disk unit, and the like, and stores system software of the test equipment, the inspection program, data of test results, and the like.

The chamber 13 is a thermostat chamber that keeps its inside at a predetermined temperature and is capable of housing, for example, ca. 30 to 60 tester boards 12 mounted with the semiconductor devices 11 with constant spacing in the vertical and horizontal directions. The semiconductor devices 11 housed in this way are heated to, for example, 125±3 degrees C.

In FIG. 2 representing the tester board 12, the right half from the central line shows a first main surface 12-1, and the left half therefrom shows a second main surface 12-2.

In FIG. 2, the tester board 12 is made of a glass epoxy resin laminated board and formed with, for example, a copper wiring layer, and one end of the board is provided with edge terminals 12a for electrical connection to edge connectors (not shown) on the device side. Note that the tester board 12 may be made of a material other than the glass epoxy resin, and the wiring layer can be made of a material other than copper.

On the first main surface 12-1 of the tester board 12, a plurality of sockets 16 to be mounted with the semiconductor devices 11, respectively, are attached in an array. For example, when a chip size package (CSP) of 72 pins is applied as the semiconductor device 11, about 200 sockets 16, for example, are placed per one tester board 12. That is, about 200 pieces of the semiconductor devices 11 can be mounted.

Here, the number of devices mountable on one conventional tester board is approximately 120, and therefore, the number of mountable semiconductor devices is significantly increased in the present application, and the reason will be described later.

On the second main surface 12-2 on the side opposite to the first main surface 12-1 of the tester board 12, device testing units 17 that are semiconductor integrated circuit devices not only to input predetermined test signals to the semiconductor devices 11 mounted on the respective sockets 16 attached on the first main surface 12-1 but also to evaluate the semiconductor devices 11 based on the output signals output from the semiconductor devices 11 according to the test signals are provided on the side opposite to the socket 16, respectively, with sandwiching the tester board 12 in one-to-one corresponding relation to the semiconductor devices 11.

That is, in the present application, a diagnosis circuit for the semiconductor device 11 that is a test target is constructed outside as the device testing unit 17, which represents so-called built-out self-test (BOST).

Note that one device testing unit 17 may be provided corresponding to a plurality of the semiconductor devices 11. Further, the device testing units 17 may not be a single semiconductor integrated circuit device as shown in the figure but may be a semiconductor integrated circuit device whose functions (its detail will be described later) are constructed of a plurality of electronic parts.

As shown in FIG. 3 in detail, the socket 16 is provided with a plurality of pins 16a. As described earlier, the socket 16 is to be mounted with the semiconductor device 11 that becomes a test target and the semiconductor device 11 is mounted by contacting the pins 16a of the socket 16 via leads 11a.

Such a socket 16 is mounted on a socket board 20 and provided detachably with respect to the tester board 12 via connectors 18 and 19. In other words, to the socket board 20, connectors 18 having terminals 18a engaged with the pins 16a of the socket 16, respectively, are attached. Further, the tester board 12 is attached with connectors 19 that have terminals 19a connecting respective wirings 12 formed in the tester board 12 as well as being engaged with the terminals 18a respectively and that are engaged with the connectors 18 respectively.

When the socket 16 is provided so as to be detachable with respect to the tester board 12 in this way, it becomes possible that various kinds of sockets are mounted freely on the tester board 12 corresponding to the shapes of the semiconductor devices 11 that are test target, and therefore, extremely high versatility can be obtained in the relation between the semiconductor device 11 and the tester board 12.

Note that the socket 16 may be directly attached to the tester board 12 and may not be detachable.

As shown in the figure, the wirings 12b of the tester board 12 are connected respectively to leads 17a of the semiconductor integrated circuit device that is the device testing unit 17 on the side of the second main surface 12-2.

In FIG. 3, a heat sink plate (cooling unit) 21 that cools off the device testing units 17 is attached to the tester board 12.

This heat sink plate 21 is in a plate form and attached to the tester board 12 so as to contact the device testing units 17 as shown in FIG. 4, and for example, a thermal circuit board produced by Soliton R&D Corporation is applied.

The heat sink plate 21 shown in the figure is constructed by overlaying two boards in a plate form and formed with flow paths 21a in which a liquid refrigerant (typically cooling water) flows in the inside over the entire area thereof. To one end of the heat sink plate 21 that is bent approximately perpendicularly, connectors 21b for supplying the liquid refrigerant to the flow paths 21a and connectors 21c for recovering the liquid refrigerant from the flow paths 21a are provided. Further, the device testing units 17 described before are fixed so as to be placed corresponding to the flow paths 21a in which the liquid refrigerant flows.

Note that a supporting plate 22 is attached to the tester board 12 on the side opposite to the tester board 12 with respect to the heat sink plate 21 so as to cover the entire heat sink plate 21. It is designed that, between the supporting plate 22 and the heat sink plate 21, a spacer 23 is put in the place where the device testing unit 17 is positioned and the heat sink plate 21 is allowed to securely come in contact with the device testing unit 17 so as to carry out sufficient cooling.

The semiconductor devices 11 are heated to approximately 125 degrees C. in the inside of the chamber 13, while the device testing units 17 similarly inside the chamber 13 are cooled off to, for example, 65 degrees C. or lower by such a heat sink plate 21.

A cooling unit suffices as long as it can cool off the device testing units 17, and it is not limited to the heat sink plate 21 shown in the present embodiment. Therefore, it is possible to use gas such as air as a refrigerant besides liquid. Even when a liquid is used as a refrigerant, the structure is not limited to that shown in the present embodiment.

Next, the functional structure of the device testing unit 17 will be explained with the use of FIG. 5.

As described earlier, the device testing unit 17 not only inputs a predetermined test signal to the semiconductor device 11 but also evaluates the semiconductor device 11 based on the output signal output from the semiconductor device 11 according to the test signal, and is provided with a pattern generator (PG) 17-1, a driver 17-2, a comparator 17-3, a waveform generator (WG) 17-4, an interface (I/F) 17-5, a test engine 17-6, a memory 17-7, a voltage regulator 17-8, and a parametric measurement unit (PMU) 17-9.

As long as the device testing unit 17 has the functions of burn-in test and memory test, the device testing unit 17 may include functions other than the above functions or may include only part of these functions.

Here, the pattern generator 17-1 that is one of the waveform generating units extracts parameters for waveform from tester languages and inputs a waveform to the driver 17-2.

The driver 17-2 buffers the waveform input from the pattern generator 17-1 at a predetermined voltage and inputs to the semiconductor devices 11 that are test targets.

The comparator 17-3 makes an output waveform from the semiconductor device 11 “Hi” or “Low” on the basis of a predetermined reference voltage and delivers to the test engine 17-6.

The test engine compares the waveform from the comparator 17-3 with an expected value and judges the acceptability (pass/fail) of the semiconductor device 11 as well as carries out control with an external controller.

The memory 17-7 stores information on pass/fail of the semiconductor device 11 that has been judged by the test engine 17-6 as above, an address position for every test pattern in which a failure occurs, and the like. Further, when the semiconductor device 11 is memory LSI, the memory 17-7 carries out storage of positions of failure bits, masking of the failure bits, real time measurement of the number of the failure bits, generation of test patterns for read on memory (ROM), and so forth.

The waveform generator 17-4 that is one of the waveform generating units generates any analog waveform such as sine wave, triangle wave, or rectangular wave and inputs to the semiconductor device 11.

The interface 17-5 is an interface between the host computer 15 and the device testing unit 17 and is specifically a serial interface or a parallel interface.

The voltage regulator 17-8 is an input power supply for the driver 17-2 and the semiconductor device 11 and supplies power at a predetermined voltage.

The parametric measurement unit 17-9 measures operation current and operation voltage of the semiconductor device 11, and open/short of the wirings formed on the semiconductor device 11.

In the test equipment of semiconductor devices 10 having the above structure, the tester board 12 mounted with the semiconductor devices 11 is housed in the inside of the chamber 13, the edge terminals 12a and the edge connectors are allowed to be engaged with each other, respectively, and predetermined test signals are input from the device testing units 17 to the semiconductor devices 11, respectively. Further, at the same time, air heated to a predetermined temperature by a heater (not shown) is introduced to the inside of the chamber 13, and the semiconductor devices 11 are heated to, for example, approximately 125±3 degrees C. Furthermore, a liquid refrigerant is supplied to the heat sink plate 21 to cool off the device testing units 17 in the inside of the chamber 13 to, for example, 65 degrees C. or lower. Sequentially, a burn-in test and a characteristic test are carried out with respect to the semiconductor devices 11.

In other words, the semiconductor devices 11 are allowed to be operated for a predetermined time at a temperature and a voltage higher than those of ordinary use conditions, and occurrence of initial failure is accelerated (burn-in test). By performing this, any semiconductor devices that could potentially trigger an initial failure are weeded out, and therefore, the product reliability is secured. In parallel with such a burn-in test, a test signal is input to the semiconductor device 11, the output value is compared to the expected value to judge the acceptability (pass/fail) of the semiconductor device 11, and the input-output signal, analog values of voltage, current, and the like of the voltage regulator part are measured (characteristic test) By performing these, defective items that do not have the desired characteristics are weeded out.

At this time, the device testing unit 17 that inputs and outputs test signal to and from the semiconductor device 11 is cooled off to the described temperature by the heat sink plate 21 without being heated to the temperature inside the chamber 13, and therefore, the device testing unit 17 itself is not applied with heat stress and operated under ordinary use conditions.

Note that all of the test items for the burn-in test and the characteristic test may be carried out; however, part of the test items such as alternating current (AC) test may be carried out by another test equipment.

In this way, according to the test equipment of semiconductor devices 10 according to the present application, the semiconductor devices 11 to be tested are attached on the first main surface 12-1 of the tester board 12, the device testing units 17 that have both functions of burn-in test and characteristic test are attached on the second main surface 12-2 of the tester board 12, and the burn-in test and the characteristic test are carried out while the device testing units 17 are cooled off by the heat sink plate 21 that is a cooling unit. Thus, it becomes possible to carry out simultaneous evaluation tests by the memory tester and the burn-in device, which were conventionally carried out independently. Because of this, the characteristic test can also be carried out within the time when the burn-in test is carried out, thereby making the test process for the semiconductor device 11 efficient, improving the test processing ability significantly, and allowing a reduction in test cost of the semiconductor device 11.

Further, since two kinds of devices of the burn-in device and the memory tester are integrated to one, it is possible to realize a reduction in cost of investment to the test equipment.

Furthermore, as in the case of the present embodiment, when the device testing units 17 are constructed of a single semiconductor integrated circuit device, the number of parts can be overwhelmingly decreased compared with that when the device testing unit is constructed of a plurality of separate parts, thereby making it possible to realize low cost. Still further, since the number of parts is decreased, the number of parts to be packaged on the tester board 12 becomes smaller, and therefore, cost of packaging can be minimized. Still further, a reduction in power consumption becomes possible.

Furthermore, as in the case of the present embodiment, when the device testing unit 17 is provided on the opposite side with sandwiching the tester board 12 in one to one relation to the semiconductor device 11 that is a test target, the distance between the device testing unit 17 and the semiconductor device 11 can be made short. Therefore, even when a large number of control signals are needed to carry out tests for a large number of semiconductor devices 11 simultaneously, the wiring capacity of the tester board 12 does not become larger. Owing to this, the transient response speed becomes faster, thereby allowing high-speed tests.

Specifically about this, the conventional test rate was about 10 MHz as described before; however, according to the present application, approximately 100 to 200 MHz can be realized relatively easily, and even about 400 MHz that is a bus speed for the host computer can be realized.

In this way, when the device testing unit 17 is provided on the opposite side with sandwiching the tester board 12 in one to one relation to the semiconductor device 11, the distance between the device testing unit 17 and the semiconductor device 11 can be made short. Therefore, space for wiring arrangement on the tester board 12 can be reduced, which makes it possible to attach more sockets 16 on the tester board 12, thereby realizing packaging of the semiconductor devices 11 in a high density.

Further, since the semiconductor devices that are test targets are isolated from each other and the influence of operation noise of the adjacent semiconductor device is significantly reduced, realization of making the test time short becomes possible when a number of semiconductor devices are tested simultaneously.

In the above explanation, the temperature inside the chamber 13 is made high to heat the semiconductor devices 11 to a predetermined temperature, and the device testing units 17 also present inside the chamber 13 are cooled off by the heat sink plate 21 that is a cooling unit. However, the inside of the chamber 13 may be kept at room temperature, and the semiconductor devices 11 may be individually heated by heating units such as heater.

However, particularly when the device testing units 17 are constructed of a single semiconductor integrated circuit device, the device testing units 17 are made in a high density and operated at a high speed, and therefore, a self-heating amount becomes higher. Thus, the device testing units 17 are desirably cooled off as in the present embodiment.

Note that when saving space in the cooling unit cannot be realized, the space efficiency inside the chamber 13 is hampered, and therefore, it is considered better to employ a system in which the cooling unit is in a liquid cooling system as in the present embodiment and heat is moved to the outside of the chamber 13 to be dissipated.

According to the present invention, the following effects can be offered.

That is, according to the present invention, the semiconductor devices to be tested are attached on the first main surface of the tester board, the device testing units having the both functions of burn-in test and characteristic test are attached on the second main surface, respectively, and the burn-in test and the characteristic test are carried out while the device testing units are cooled off by the cooing unit, and therefore, it becomes possible to carry out simultaneous evaluation tests by the memory tester and the burn-in device, which were conventionally carried out separately.

Owing to this, the characteristic test can be carried out within the time when the burn-in test is carried out, thereby making the test process for the semiconductor device efficient, improving the test processing ability significantly, and allowing a reduction in test cost of the semiconductor device.

Further, the distance between the device testing unit and the semiconductor device can be made short, and therefore, the transient response speed becomes faster, thereby allowing high-speed tests. Furthermore, since space for wiring arrangement on the tester board can be reduced, realization of packaging of the semiconductor devices in a high density becomes possible.

Still further, since the semiconductor devices that are test targets are isolated from each other and the influence of operation noise of the adjacent semiconductor device is significantly reduced, realization of making the test time short becomes possible when a number of semiconductor devices are tested simultaneously.

What is claimed is:

1. A test equipment of semiconductor devices comprising:
a chamber;
a tester board that can be housed in the inside of the chamber;
a plurality of sockets that are attached on a first main surface of the tester board and mounted with semiconductor devices to be tested;
a plurality of device testing units that are attached on a second main surface on the side opposite to the first main surface of the tester board, and input predetermined test signals to one or a plurality of the semiconductor devices as well as evaluate the semiconductor devices based on the output signals output from the semiconductor devices according to the test signals; and
a cooling unit that cools off the device testing units,
wherein a burn-in test and a characteristic test for the semiconductor devices are carried out while the semiconductor devices mounted on the sockets respectively are heated and the device testing units are cooled off by the cooling unit in the chamber.

2. A test equipment of semiconductor devices comprising:
a chamber;
a tester board that can be housed in the inside of the chamber;
a plurality of sockets that are attached on a first main surface of the tester board and mounted with semiconductor devices to be tested;
device testing units that are provided on a second main surface on the side opposite to the first main surface of the tester board with sandwiching the tester board in one to one relation to the semiconductor devices mounted on the sockets respectively and input predetermined test signals to the semiconductor devices as well as evaluate the semiconductor devices based on the output signals output from the semiconductor devices according to the test signals; and
a cooling unit that cools off the device testing units,
wherein the device testing unit is provided with a waveform generating unit that generates a waveform input to the semiconductor device, and
a burn-in test and a characteristic test for the semiconductor devices are carried out while the semiconductor devices mounted on the sockets respectively are heated and the device testing units are cooled off by the cooling unit in the chamber.

3. The test equipment of semiconductor devices according to claim 1, wherein the cooling unit is a heat sink plate that is attached to the tester board so as to come in contact with the device testing units and formed with flow paths where a liquid refrigerant flows in the inside of the heat sink plate.

4. The test equipment of semiconductor devices according to claim 2, wherein the cooling unit is a heat sink plate that is attached to the tester board so as to come in contact with the device testing units and formed with flow paths where a liquid refrigerant flows in the inside of the heat sink plate.

5. A test equipment of semiconductor devices comprising:
a chamber;
a tester board that can be housed in the inside of the chamber;
a plurality of sockets that are attached on a first main surface of the tester board and mounted with semiconductor devices to be tested;
a plurality of device testing units that are attached on a second surface on the side opposite to the first main surface of the tester board, and input predetermined test signals to one or a plurality of the semiconductor devices as well as evaluate the semiconductor devices based on the output signals output from the semiconductor devices according to the test signals; and
a heating unit that heats the semiconductor devices,
wherein a burn-in test and a characteristic test are carried out while the semiconductor devices mounted on the sockets respectively are heated by the heating unit.

6. A test equipment of semiconductor devices comprising:
a chamber;
a tester board that can be housed in the inside of the chamber;
a plurality of sockets that are attached on a first main surface of the tester board and mounted with semiconductor devices to be tested;
device testing units that are provided on a second main surface on the side opposite to the first main surface of the tester board with sandwiching the tester board in one to one relation to the semiconductor devices mounted on the sockets respectively and input predetermined test signals to the semiconductor devices as well as evaluate the semiconductor devices based on the output signals output from the semiconductor devices according to the test signals; and
a heating unit that heats the semiconductor devices,
wherein the device testing unit is provided with a waveform generating unit that generates a waveform input to the semiconductor device, and
a burn-in test and a characteristic test are carried out while the semiconductor devices mounted on the sockets respectively are heated by the heating unit.

7. The test equipment of semiconductor devices according to claim 2, wherein the waveform generating unit is at least any one of a pattern generating unit and a waveform generating unit.

8. The test equipment of semiconductor devices according to claim 6, wherein the waveform generating unit is at least any one of a pattern generating unit and a waveform generating unit.

9. The test equipment of semiconductor devices according to claim 1, wherein the device testing unit further includes a driver that inputs a generated waveform to the semiconductor device.

10. The test equipment of semiconductor devices according to claim 2, wherein the device testing unit further includes a driver that inputs a generated waveform to the semiconductor device.

11. The test equipment of semiconductor devices according to claim 5, wherein the device testing unit further includes a driver that inputs a generated waveform to the semiconductor device.

12. The test equipment of semiconductor devices according to claim 6, wherein the device testing unit further includes a driver that inputs a generated waveform to the semiconductor device.

13. The test equipment of semiconductor devices according to claim 1, wherein the device testing units are constructed of a single semiconductor integrated circuit device.

14. The test equipment of semiconductor devices according to claim 2, wherein the device testing units are constructed of a single semiconductor integrated circuit device.

15. The test equipment of semiconductor devices according to claim 5, wherein the device testing units are constructed of a single semiconductor integrated circuit device.

16. The test equipment of semiconductor devices according to claim 6, wherein the device testing units are constructed of a single semiconductor integrated circuit device.

17. The test equipment of semiconductor devices according to claim 1, wherein the socket is provided detachable with respect to the tester board via connectors.

18. The test equipment of semiconductor devices according to claim 2, wherein the socket is provided detachable with respect to the tester board via connectors.

19. The test equipment of semiconductor devices according to claim 5, wherein the socket is provided detachable with respect to the tester board via connectors.

20. The test equipment of semiconductor devices according to claim 6, wherein the socket is provided detachable with respect to the tester board via connectors.
